(19) United States
(12) Patent Application Publication
(10) Pub. No.: US 2026/0038597 A1
(43) Pub. Date: Feb. 5, 2026

(54) SEMICONDUCTOR MEMORY DEVICE

(71) Applicant: Kioxia Corporation, Tokyo (JP)

(72) Inventors: Yuki INUZUKA, Yokohama Kanagawa (JP); Akiyuki MURAYAMA, Koto Tokyo (JP)

(21) Appl. No.: 19/074,222

(22) Filed: Mar. 7, 2025

(30) Foreign Application Priority Data
Aug. 2, 2024 (JP) 2024-128063

(51) Int. Cl. G11C 16/10; G11C 16/08; G11C 16/24; G11C 16/32

(52) U.S. Cl. CPC G11C 16/102; G11C 16/08; G11C 16/24; G11C 16/32

(57) ABSTRACT

A semiconductor memory device includes a memory cell array including a first block and a second block, and a control circuit. The control circuit executes a first write operation of writing first data by applying a first voltage to a channel area of a first memory cell transistor of the first block through a bit line and then while the channel area of the first memory cell transistor is in a floating state, applying a program voltage to a first word line. The control circuit starts a second write operation of writing second data into a second memory cell transistor of the second block that is connected to the bit line while the program voltage is applied to the first word line.

### CROSS-REFERENCE TO RELATED APPLICATION(S)

This application is based upon and claims the benefit of priority from Japanese Patent Application No. 2024-128063, filed Aug. 2, 2024, the entire contents of which are incorporated herein by reference.

### FIELD

Embodiments described herein relate generally to a semiconductor memory device.

### BACKGROUND

A NAND flash memory is known as a semiconductor memory device.

### BRIEF DESCRIPTION OF THE DRAWINGS

FIG. 1 is a block diagram illustrating a schematic configuration of a memory system according to an embodiment.

FIG. 2 is a block diagram illustrating a schematic configuration of a semiconductor memory device according to the embodiment.

FIG. 3 is a circuit diagram illustrating a configuration of the semiconductor memory device according to the embodiment.

FIG. 4 is a cross-sectional view illustrating a cross-sectional structure of the semiconductor memory device according to the embodiment.

FIGS. 5A and 5B are diagrams illustrating an operation of the semiconductor memory device.

FIG. 6 is a block diagram illustrating a configuration of a sense amplifier unit according to the embodiment.

FIG. 7 is a diagram illustrating an example of a threshold distribution of a memory cell transistor.

FIG. 8 is a diagram illustrating a change in a voltage of various wires during a program operation.

FIGS. 9A to 9L are timing charts illustrating transitions of voltages of each of a bit line, a select gate line, a word line, and a source line during a write operation of the semiconductor memory device according to the embodiment.

FIGS. 10A and 10B are diagrams schematically illustrating operation examples of a semiconductor memory device according to a reference example and the semiconductor memory device according to the embodiment.

FIGS. 11A and 11B are timing charts schematically illustrating operation examples of the semiconductor memory device according to the reference example and the semiconductor memory device according to the embodiment.

FIGS. 12A to 12L are timing charts illustrating transitions of voltages of each of a bit line, a select gate line, a word line, and a source line during a write operation of a semiconductor memory device according to a modification example of the embodiment.

FIGS. 13A to 13L are timing charts illustrating transitions of voltages of each of a bit line, a select gate line, a word line, and a source line during a write operation of a semiconductor memory device according to another embodiment.

### DETAILED DESCRIPTION

Embodiments provide a semiconductor memory device capable of improving a speed of a write operation.

In general, according to one embodiment, a semiconductor memory device includes a memory cell array including a first block and a second block, each of which includes a plurality of memory cell transistors, and a control circuit that controls the memory cell array. The first block includes a first memory cell transistor of which a gate is connected to a first word line. The second block includes a second memory cell transistor of which a gate is connected to a second word line. The control circuit executes a first write operation of writing first data into the first memory cell transistor by applying a first voltage to a channel area of the first memory cell transistor through a bit line, then causing the channel area of the first memory cell transistor to enter a floating state, and while the channel area of the first memory cell transistor is in the floating state, applying a program voltage to the first word line for a first time period, and starts a second write operation of writing second data into the second memory cell transistor connected to the bit line during the first time period while the program voltage is applied to the first word line.

According to the semiconductor memory device according to the present disclosure, a speed of a write operation can be improved.

Hereinafter, embodiments will be described with reference to the drawings. For easy understanding of description, identical elements in each drawing will be designated by identical reference numerals as much as possible, and description of such elements will not be repeated.

1 Embodiment

A semiconductor memory device according to an embodiment will be described. A semiconductor memory device according to the present embodiment is a non-volatile memory device configured as a NAND flash memory.

1.1 Configuration of Memory System

First, a configuration of a memory system according to the present embodiment will be described.

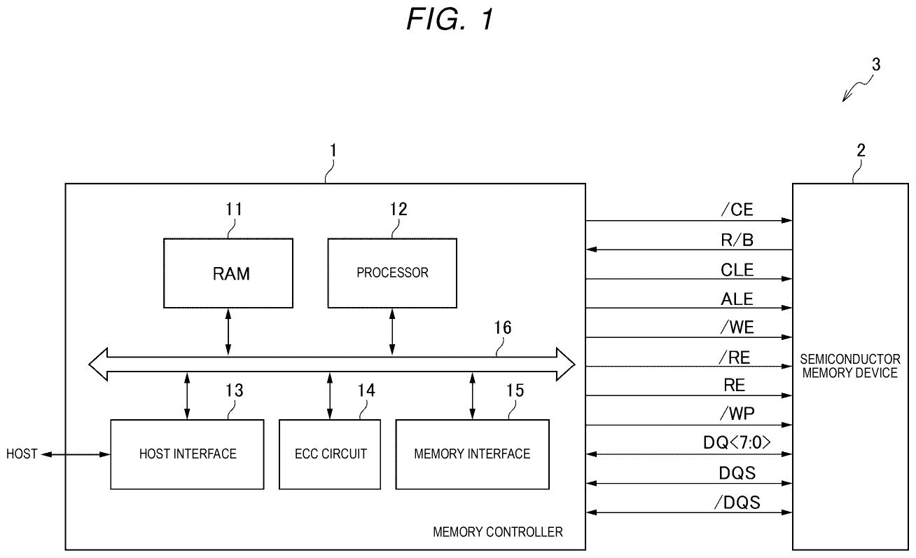

As illustrated in FIG. 1, a memory system 3 according to the present embodiment includes a memory controller 1 and a semiconductor memory device 2. The semiconductor memory device 2 is a non-volatile memory device configured as a NAND flash memory. The memory system 3 is connectable to a host. For example, the host is an electronic device such as a personal computer or a portable terminal.

The memory controller 1 controls writing of data into the semiconductor memory device 2 in response to a write request from the host. The memory controller 1 controls reading of data from the semiconductor memory device 2 in response to a read request from the host.

Each of a chip enable signal/CE, a ready busy signal R/B, a command latch enable signal CLE, an address latch enable signal ALE, a write enable signal/WE, read enable signals/RE and RE, a write protect signal/WP, a signal DQ<7:0>, and data strobe signals DQS and/DQS is communicated between the memory controller 1 and the semiconductor memory device 2.

The chip enable signal/CE is transmitted to the semiconductor memory device 2 from the memory controller 1. The chip enable signal/CE is a signal for enabling the semiconductor memory device 2. The ready busy signal R/B is transmitted to the memory controller 1 from the semiconductor memory device 2. The ready busy signal R/B is a signal for indicating whether the semiconductor memory device 2 is in a ready state or a busy state. For example, the term “ready state” means a state capable of receiving an instruction from an outside. The term “busy state” means a state not capable of receiving an instruction from the outside.

The command latch enable signal CLE is transmitted to the semiconductor memory device 2 from the memory controller 1. The command latch enable signal CLE is a signal indicating that the signal DQ<7:0> is a command. The address latch enable signal ALE is transmitted to the semiconductor memory device 2 from the memory controller 1. The address latch enable signal ALE is a signal indicating that the signal DQ<7:0> is an address. The write enable signal/WE is transmitted to the semiconductor memory device 2 from the memory controller 1. The write enable signal/WE is a signal for instructing the semiconductor memory device 2 to acquire the signal DQ<7:0> and is asserted each time the memory controller 1 receives a command, an address, or data through the signal DQ<7:0>. The memory controller 1 instructs the semiconductor memory device 2 to acquire the signal DQ<7:0>while the signal/WE is at a level “Low (L)”.

The read enable signal/RE is transmitted to the semiconductor memory device 2 from the memory controller 1. The signal RE is a signal complementary to the signal/RE. The read enable signals/RE and RE are signals for reading data from the semiconductor memory device 2 via the memory controller 1. For example, the read enable signals/RE and RE are used to control an operation timing of the semiconductor memory device 2 in outputting the data signal DQ<7:0>. The signal DQ<7:0>contains data communicated between the semiconductor memory device 2 and the memory controller 1 and includes a command, an address, or data (e.g., read data or write data). The data strobe signal DQS is a timing control signal communicated between the semiconductor memory device 2 and the memory controller 1 in conjunction with the data signal DQ<7:0>. The signal/DQS is a signal complementary to the signal DQS. The data strobe signals DQS and/DQS are signals for controlling input and output timings of the data signal DQ<7:0>.

The memory controller 1 includes a RAM 11, a processor 12, a host interface 13, an ECC circuit 14, and a memory interface 15. These elements are connected to each other by an internal bus 16.

The host interface 13 outputs a request, user data (write data), and the like received from the host to the internal bus 16. The host interface 13 transmits user data read from the semiconductor memory device 2 and a response and the like from the processor 12 to the host.

The memory interface 15 controls a process of writing the user data and the like into the semiconductor memory device 2 and a process of reading the user data from the semiconductor memory device 2, based on an instruction of the processor 12.

The processor 12 controls the memory controller 1. The processor 12 is a CPU, an MPU, or the like. When the processor 12 receives a request from the host through the host interface 13, the processor 12 performs a control corresponding to the request. For example, the processor 12 instructs the memory interface 15 to write the user data and parity into the semiconductor memory device 2 in accordance with the request from the host. The processor 12 instructs the memory interface 15 to read the user data and parity from the semiconductor memory device 2 in accordance with the request from the host.

The processor 12 determines a storage area (a memory area) on the semiconductor memory device 2 for the user data stored in the RAM 11. The user data is stored in the RAM 11 through the internal bus 16. The processor 12 determines the memory area for data in page units (page data) that are units of writes. Hereinafter, the user data stored in one page of the semiconductor memory device 2 will be referred to as “unit data”. The unit data is generally encoded and stored in the semiconductor memory device 2 as a code word. Encoding is optional in the present embodiment. While the memory controller 1 may store the unit data in the semiconductor memory device 2 without encoding the unit data, FIG. 1 illustrates a configuration of performing encoding as an example. When the memory controller 1 does not perform encoding, page data matches the unit data. One code word may be generated based on one piece of unit data, or one code word may be generated based on divided data obtained by dividing the unit data. One code word may be generated using a plurality of pieces of unit data.

For each unit data, the processor 12 determines the memory area of the semiconductor memory device 2 as a write destination. A physical address is allocated to the memory area of the semiconductor memory device 2. The processor 12 manages the memory area as the write destination of the unit data using the physical address. The processor 12 instructs the memory interface 15 to write the user data into the semiconductor memory device 2 by designating the determined memory area (the physical address). The processor 12 manages a correspondence between a logical address (a logical address managed by the host) and the physical address of the user data. When the processor 12 receives the read request including the logical address from the host, the processor 12 specifies the physical address corresponding to the logical address and instructs the memory interface 15 to read the user data by designating the physical address.

The ECC circuit 14 generates the code word by encoding the user data stored in the RAM 11. The ECC circuit 14 decodes the code word read from the semiconductor memory device 2.

The RAM 11 temporarily stores the user data received from the host before storing the user data in the semiconductor memory device 2 or temporarily stores data read from the semiconductor memory device 2 before transmitting the data to the host. For example, the RAM 11 is a general-purpose memory such as an SRAM or a DRAM.

FIG. 1 illustrates a configuration example in which the memory controller 1 includes the ECC circuit 14 and the memory interface 15. Meanwhile, the ECC circuit 14 may be incorporated into the memory interface 15. The ECC circuit 14 may be incorporated into the semiconductor memory device 2. The configuration and disposition of each element illustrated in FIG. 1 are not limited to the configuration and disposition specifically depicted in FIG. 1.

When the write request is received from the host, the memory system 3 in FIG. 1 operates as follows. The processor 12 temporarily stores data to be written in the RAM 11. The processor 12 reads and inputs the data stored in the RAM 11 into the ECC circuit 14. The ECC circuit 14 encodes the input data and inputs the code word into the memory interface 15. The memory interface 15 writes the input code word into the semiconductor memory device 2.

When the read request is received from the host, the memory system 3 in FIG. 1 operates as follows. The memory interface 15 inputs the code word read from the semiconductor memory device 2 into the ECC circuit 14. The ECC circuit 14 decodes the input code word and stores the decoded data in the RAM 11. The processor 12 transmits the data stored in the RAM 11 to the host through the host interface 13.

### 1.2 Schematic Configuration of Semiconductor Memory Device

Next, a schematic configuration of the semiconductor memory device 2 will be described.

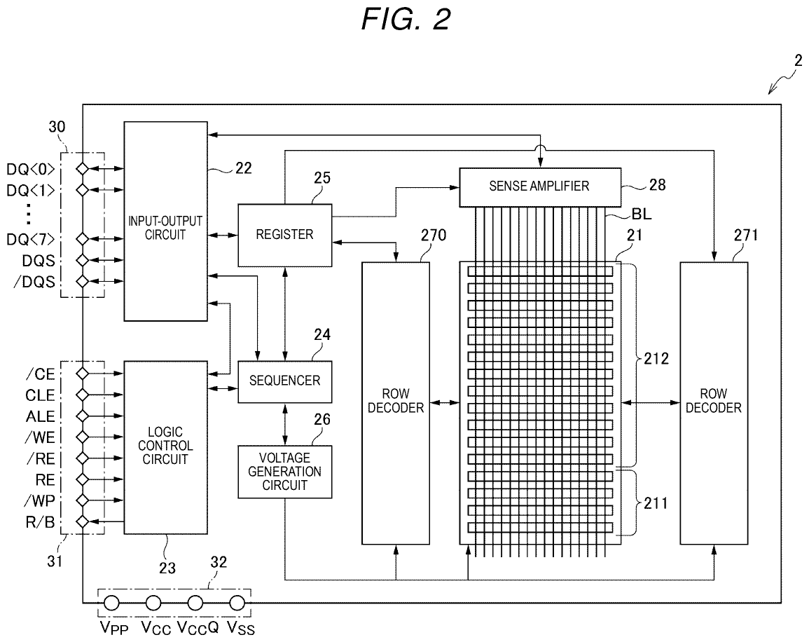

As illustrated in FIG. 2, the semiconductor memory device 2 includes a memory cell array 21, an input-output circuit 22, a logic control circuit 23, a sequencer 24, a register 25, a voltage generation circuit 26, row decoders 270 and 271, a sense amplifier 28, an input-output pad group 30, a logic control pad group 31, and a power supply input terminal group 32.

The memory cell array 21 is a part storing data. The memory cell array 21 includes a plurality of memory cell transistors associated with a plurality of word lines and with a plurality of bit lines BL. In FIG. 2, the bit lines BL are schematically illustrated, and the word lines are not illustrated. The memory cell array 21 includes a first block group 211 and a second block group 212. The first block group 211 includes a plurality of blocks BLKa₀ to BLKa₂ₚ₊₁. The second block group 212 includes a plurality of blocks BLKb₀ to BLKb_{2q+1}. Here, p and q are integers satisfying a relationship of 0<p<q. Each of a block BLKa and a block BLKb is configured with a set of a plurality of memory cell transistors. In the memory cell array 21, the first block group 211 is used as a cache area, and the second block group 212 is used as a storage area. That is, in reading data, data read from the memory cell transistor of the second block group 212 is temporarily stored in the memory cell transistor of the first block group 211, and then the data temporarily stored in the memory cell transistor of the first block group 211 is acquired by the sense amplifier 28. In writing data, data transmitted from the sense amplifier 28 is temporarily stored in the memory cell transistor of the first block group 211, and then the data stored in the memory cell transistor of the first block group 211 is stored in the memory cell transistor of the second block group 212.

The input-output circuit 22 communicates the signal DQ<7:0> and the data strobe signals DQS and/DQS with the memory controller 1. The input-output circuit 22 transmits the command and the address in the signal DQ<7:0> to the register 25. The input-output circuit 22 communicates write data and read data with the sense amplifier 28.

The logic control circuit 23 receives the chip enable signal/CE, the command latch enable signal CLE, the address latch enable signal ALE, the write enable signal/WE, the read enable signals/RE and RE, and the write protect signal/WP from the memory controller 1. The logic control circuit 23 transmits a state of the semiconductor memory device 2 to the outside by transmitting the ready busy signal R/B to the memory controller 1.

The register 25 temporarily stores various types of data. For example, the register 25 stores a command for providing instructions for a write operation, a read operation, and an erasing operation. This command is input into the input-output circuit 22 from the memory controller 1 and is then transmitted to and stored in the register 25 from the input-output circuit 22. The register 25 also stores an address corresponding to the command. This address is input into the input-output circuit 22 from the memory controller 1 and is then transmitted to and stored in the register 25 from the input-output circuit 22.

The sequencer 24 controls an operation of each portion including the memory cell array 21 based on control signals input into the input-output circuit 22 and the logic control circuit 23 from the memory controller 1. In the present embodiment, the sequencer 24 is an example of a control circuit.

The voltage generation circuit 26 is a part that generates a voltage required for each of the write operation, the read operation, and the erasing operation of data in the memory cell array 21. For example, this voltage includes a voltage applied to each of the plurality of word lines and the plurality of bit lines BL of the memory cell array 21. The operation of the voltage generation circuit 26 is controlled by the sequencer 24.

The row decoders 270 and 271 are circuits configured with switch groups for applying voltages to each of the plurality of word lines of the memory cell array 21. More specifically, one row decoder 270 applies a voltage to the word lines corresponding to the even-numbered blocks BLKa₀, BLKa₂, . . . , BLKa₂ₚ provided in the first block group 211 and the word lines corresponding to the even-numbered blocks BLKb₀, BLKa₂, . . . , BLKa_{2q} provided in the second block group 212 of the memory cell array 21. The other row decoder 271 applies a voltage to the word lines corresponding to the odd-numbered blocks BLKa₁, BLKa₃, . . . , BLKa₂ₚ₊₁ provided in the first block group 211 and the word lines corresponding to the odd-numbered blocks BLKb₁, BLKa₃, . . . , BLKa_{2q+1} provided in the second block group 212 of the memory cell array 21. The row decoders 270 and 271 receive a block address and a row address from the register 25, select a block based on the block address, and select a word line based on the row address. The row decoders 270 and 271 switch between open and closed states of the switch groups such that the voltage from the voltage generation circuit 26 is applied to the selected word line. The operations of the row decoders 270 and 271 are controlled by the sequencer 24. Hereinafter, the row decoder 270 will be referred to as the “even-numbered row decoder 270”, and the row decoder 271 will be referred to as the “odd-numbered row decoder 271”. In the present embodiment, the even-numbered row decoder 270 is an example of a first row decoder, and the odd-numbered row decoder 271 is an example of a second row decoder.

The sense amplifier 28 is a circuit for adjusting the voltage to be applied to the bit line BL of the memory cell array 21 or reading and converting the voltage of the bit line BL into data. In reading data, the sense amplifier 28 acquires the read data based on a data signal read into the bit line BL from the memory cell transistor of the memory cell array 21 and transmits the acquired read data to the input-output circuit 22. In writing data, the sense amplifier 28 controls the bit line BL while performing a programming operation on the memory cell transistor to store data to be written in the memory cell transistor. The operation of the sense amplifier 28 is controlled by the sequencer 24.

Both of the input-output circuit 22 and the logic control circuit 23 are circuits configured as parts in which signals are input into and output from the memory controller 1. That is, the input-output circuit 22 and the logic control circuit 23 are provided as interface circuits of the semiconductor memory device 2.

The input-output pad group 30 is a part in which a plurality of terminals (pads) for communicating each signal between the memory controller 1 and the input-output circuit 22 are provided. Each terminal is individually provided in accordance with each of the signal DQ<7:0> and the data strobe signals DQS and/DQS.

The logic control pad group 31 is a part in which a plurality of terminals (pads) for communicating each signal between the memory controller 1 and the logic control circuit 23 are provided. Each terminal is individually provided in accordance with the chip enable signal/CE, the command latch enable signal CLE, the address latch enable signal ALE, the write enable signal/WE, the read enable signals/RE and RE, the write protect signal/WP, and the ready busy signal R/B.

The power supply input terminal group 32 is a part in which a plurality of terminals for receiving application of each voltage required for the operation of the semiconductor memory device 2 are provided. The voltages applied to each terminal include power supply voltages VCC, VCCQ, and VPP and a ground voltage VSS. For example, the power supply voltage VCC is a circuit power supply voltage provided from the outside as an operation power supply and is a voltage of approximately 2.5 V. For example, the power supply voltage VCC is a voltage for generating a voltage VDD that is an internal power supply voltage of the semiconductor memory device 2. For example, the power supply voltage VDD is a voltage of about 1.5 V. For example, the power supply voltage VCCQ is a power supply voltage lower than the power supply voltage VCC and is a voltage of 1.2 V. The power supply voltage VCCQ is an input-output power supply voltage used in communicating signals between the memory controller 1 and the semiconductor memory device 2. The power supply voltage VCCQ is supplied to at least a driver circuit and a receiver circuit (not illustrated) of the input-output circuit 22. For example, the power supply voltage VPP is a power supply voltage higher than the power supply voltage VCC and is a voltage of 12 V.

### 1.3 Circuit Configuration of Memory Cell Array

Hereinafter, a circuit configuration of the memory cell array 21 will be described.

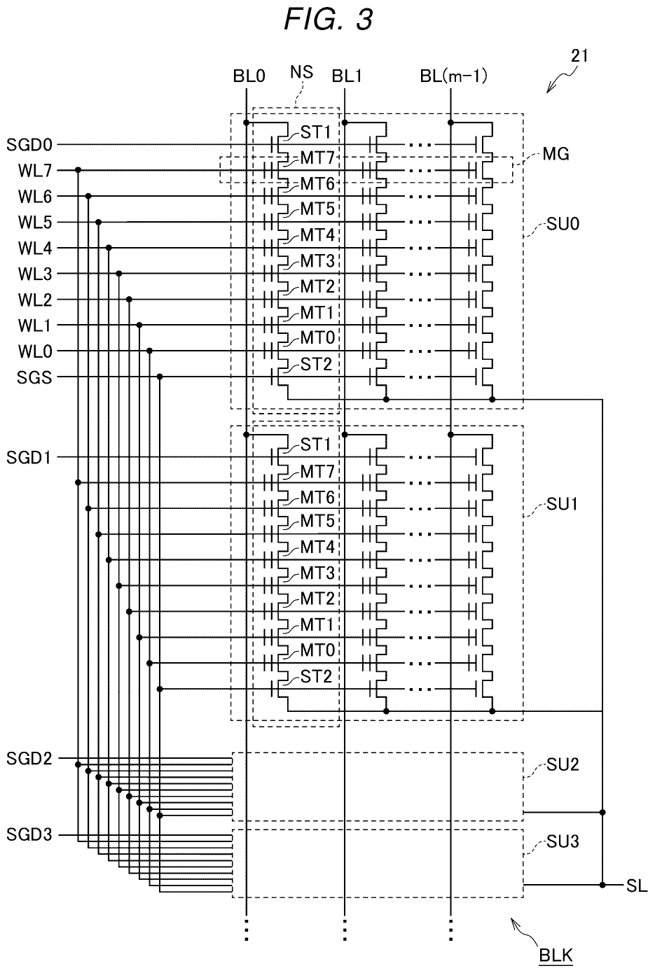

As illustrated in FIG. 3, the memory cell array 21 is configured with a plurality of blocks BLK. FIG. 3 illustrates only one of the plurality of blocks BLK. Other blocks BLK provided in the memory cell array 21 have the same configuration as illustrated in FIG. 3.

As illustrated in FIG. 3, for example, the block BLK includes four string units SU (SU0 to SU3). Each string unit SU includes a plurality of NAND strings NS. For example, each NAND string NS includes eight memory cell transistors MT (MT0 to MT7) and select transistors ST1 and ST2.

The memory cell transistors MT are disposed in serial connection between the select transistor ST1 and the select transistor ST2. The memory cell transistor MT7 on one end side is connected to a source of the select transistor ST1, and the memory cell transistor MT0 on the other end side is connected to a drain of the select transistor ST2.

Gates of the select transistors ST1 of the string units SU0 to SU3 are connected in common to select gate lines SGDO to SGD3, respectively. Gates of the select transistors ST2 are connected in common to the same select gate line SGS across the plurality of string units SU in the same block BLK. Gates of the memory cell transistors MT0 to MT7 in the same block BLK are connected in common to word lines WL0 to WL7, respectively. That is, the word lines WL0 to WL7 and the select gate line SGS are common to the plurality of string units SU0 to SU3 in the same block BLK, and select gate lines SGD are individually provided for each of the string units SU0 to SU3 in the same block BLK.

The memory cell array 21 is provided with m bit lines BL (BLO, BLI, . . . , BL (m-1)). Here, “m” is an integer corresponding to the number of NAND strings NS provided in one string unit SU. A drain of the select transistor ST1 of each NAND string NS is connected to a corresponding bit line BL. A source of the select transistor ST2 of each NAND string NS is connected to a source line SL. The source line SL is common to the sources of a plurality of select transistors ST2 provided in the block BLK.

In the following description, a set of 1-bit data stored in a plurality of memory cell transistors MT that are connected to one word line WL and that belong to one string unit SU will be referred to as a “page”. In FIG. 3, one set configured with the plurality of memory cell transistors MT is designated by reference numeral “MG”.

The data stored in the plurality of memory cell transistors MT in the same block BLK are collectively erased. Meanwhile, reading and writing of data are collectively performed for the plurality of memory cell transistors MT that are connected to one word line WL and that belong to one string unit SU.

The memory cell transistor MT provided in the first block group 211 illustrated in FIG. 1 can store data of 1 bit. That is, the semiconductor memory device 2 supports a single-level cell (SLC) method of storing 1-bit data in one memory cell transistor MT as a writing method of data into the memory cell transistors MT of the first block group 211.

Meanwhile, the memory cell transistor MT provided in the second block group 212 can store data of 3 bits including an upper bit, a middle bit, and a lower bit. That is, the semiconductor memory device 2 employs a triple-level cell (TLC) method of storing 3-bit data in one memory cell transistor MT as a writing method of data into the memory cell transistors MT of the second block group 212. Instead of this aspect, a multi-level cell (MLC) method of storing 2-bit data in one memory cell transistor MT, a quad-level cell (QLC) method of storing 4-bit data in one memory cell transistor MT, or the like may be employed as the writing method of data into the memory cell transistors MT of the second block group 212. In general, the number of bits of data to be stored in one memory cell transistor MT is not limited to any one particular number.

Hereinafter, for distinction between the memory cell transistors MT provided in each of the first block group 211 and the second block group 212, the memory cell transistor MT of the first block group 211 will be referred to as a “memory cell transistor MTa”, and the memory cell transistor MT of the second block group 212 will be referred to as a “memory cell transistor MTb”. As illustrated in FIG. 2, the plurality of bit lines BL are common across the plurality of blocks BLK provided in the first block group 211 and the plurality of blocks BLK provided in the second block group 212.

### 1.4 Cross-Sectional Structure of Semiconductor Memory Device

Next, a structure of the memory cell array 21 and its surrounding area will be described.

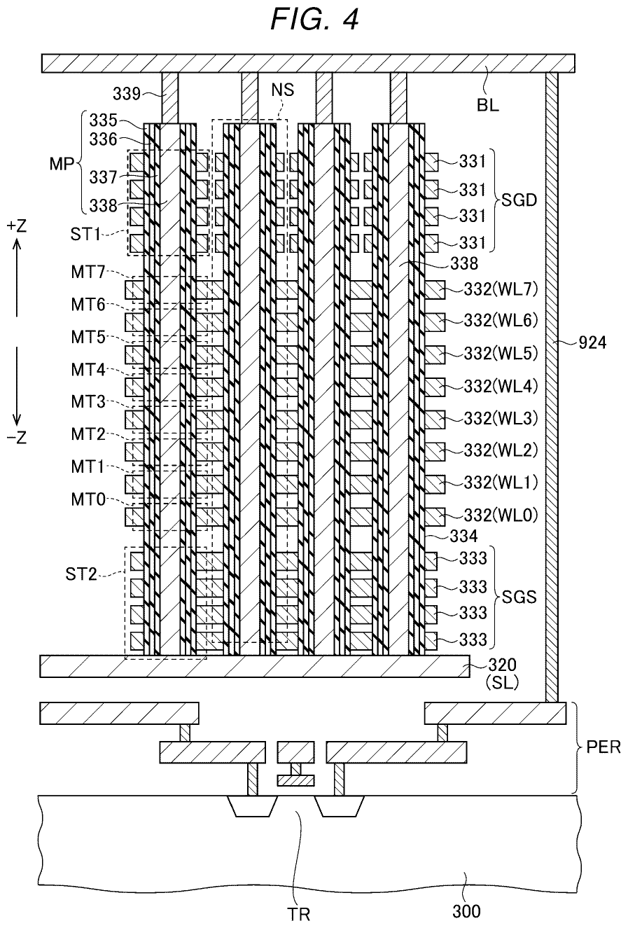

As illustrated in FIG. 4, in the memory cell array 21, the plurality of NAND strings NS are formed on a conductor layer 320. The conductor layer 320 is referred to as a buried source line (BSL) and corresponds to the source line SL illustrated in FIG. 3.

A plurality of wiring layers 333 functioning as the select gate line SGS, a plurality of wiring layers 332 functioning as the word lines WL, and a plurality of wiring layers 331 functioning as the select gate lines SGD are stacked above each other and above the conductor layer 320. Insulating layers (not illustrated) are disposed between adjacent wiring layers 333, 332, and 331.

A plurality of memory holes 334 are formed in the memory cell array 21. The memory hole 334 is a hole that passes through the wiring layers 333, 332, and 331 and the insulating layers (not illustrated) among the wiring layers 333, 332, and 331 in an up-down direction and that reaches the conductor layer 320. A block insulating film 335, a charge storage layer 336, and a gate insulating film 337 are formed in this order on a side surface of the memory hole 334, and a column conductor 338 is buried inside the memory hole 334. For example, the column conductor 338 is made of polysilicon and functions as an area in which a channel is formed during the operations of the memory cell transistor MT and the select transistors ST1 and ST2 provided in the NAND string NS. Hereinafter, a columnar body configured with the block insulating film 335, the charge storage layer 336, the gate insulating film 337, and the column conductor 338 inside the memory hole 334 will be referred to as a memory pillar MP.

Each part of the memory pillar MP intersecting with each of the wiring layers 333, 332, and 331 stacked on each other functions as a transistor. Among these plurality of transistors, transistors in the part intersecting with the wiring layers 331 function as the select transistors ST1. Among the plurality of transistors, transistors in the part intersecting with the wiring layers 332 function as the memory cell transistors MT (MT0 to MT7). Among the plurality of transistors, transistors in the part intersecting with the wiring layers 333 function as the select transistors ST2. Such a configuration causes the memory pillar MP to function as the NAND string NS illustrated in FIG. 3. The column conductor 338 inside the memory pillar MP is a part functioning as channels of the memory cell transistor MT and the select transistors ST1 and ST2.

A wiring layer functioning as the bit line BL is formed above the column conductor 338. A contact plug 339 that connects the column conductor 338 and the bit line BL to each other is formed at an upper end of the column conductor 338.

A plurality of the same configuration as the configuration illustrated in FIG. 4 are arranged along a direction normal to the drawing of FIG. 4. One string unit SU is formed by a set of a plurality of NAND strings NS linearly arranged along the direction normal to the drawing of FIG. 4.

In the semiconductor memory device 2 according to the present embodiment, a peripheral circuit PER is provided below the memory cell array 21, that is, at a position between the memory cell array 21 and a semiconductor substrate 300. The peripheral circuit PER is a circuit for implementing the write operation, the read operation, the erasing operation, and the like of data in the memory cell array 21. The sense amplifier 28, the row decoders 270 and 271, the voltage generation circuit 26, and the like illustrated in FIG. 2 are parts of the peripheral circuit PER. The peripheral circuit PER includes various transistors, RC circuits, and the like. In the example illustrated in FIG. 4, a transistor TR formed on the semiconductor substrate 300 and the bit line BL above the memory cell array 21 are electrically connected to each other through a contact 924.

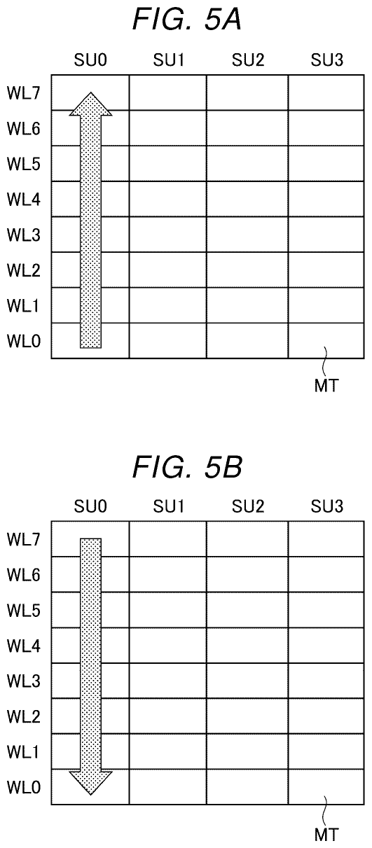

FIG. 5A illustrates an operation example of the semiconductor memory device 2.

In this case, the sense amplifier 28, in writing data into the memory cell transistors MT on each NAND string NS, sequentially writes data from the memory cell transistor MT0 on the word line WL0 to the memory cell transistor MT7 on the word line WL7. That is, the sense amplifier 28 sequentially performs writing on the memory cell transistors MT in a direction from a lower end to an upper end of the memory pillar MP (a +Z direction illustrated in FIG. 4). This writing will be referred to as a normal order program (NOP) method.

Meanwhile, FIG. 5B illustrates another operation example of the semiconductor memory device 2. In this case, the sense amplifier 28, in writing data into the memory cell transistors MT on each NAND string NS, sequentially writes data from the memory cell transistor MT7 on the word line WL7 to the memory cell transistor MT0 on the word line WL0. That is, the sense amplifier 28 sequentially performs writing on the memory cell transistors MT in a direction from the upper end to the lower end of the memory pillar MP (a-Z direction illustrated in FIG. 4). This writing will be referred to as a reverse order program (ROP) method.

### 1.5 Configuration of Sense Amplifier

Next, a circuit configuration of the sense amplifier 28 will be described.

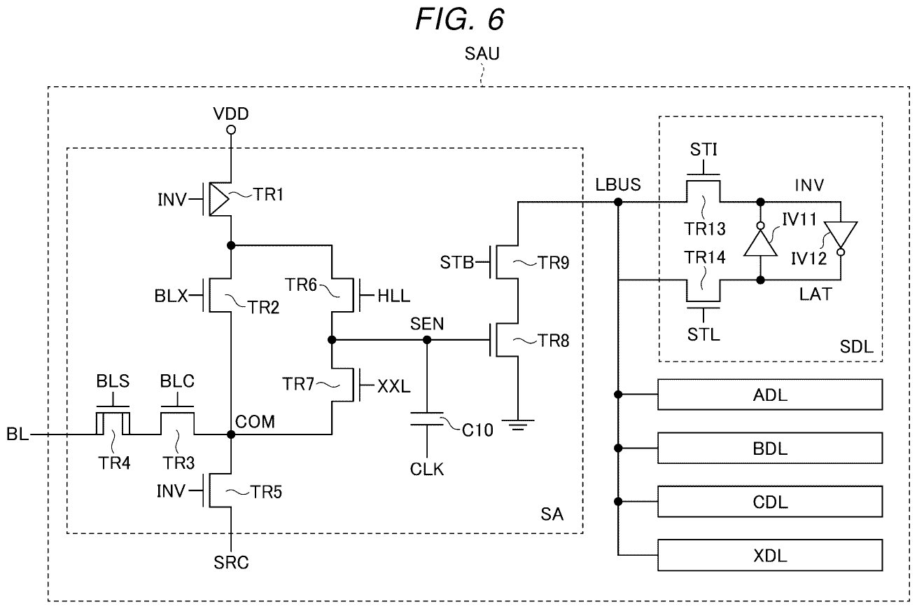

The sense amplifier 28 includes a plurality of sense amplifier units associated with the plurality of bit lines BL, respectively. FIG. 6 illustrates a circuit configuration of one sense amplifier unit SAU taken from the sense amplifier units.

As illustrated in FIG. 6, the sense amplifier unit SAU includes a sense amplifier portion SA and latch circuits SDL, ADL, BDL, CDL, and XDL. The sense amplifier portion SA and the latch circuits SDL, ADL, BDL, CDL, and XDL are connected by a bus LBUS to be capable of communicating data with each other.

For example, in the read operation, the sense amplifier portion SA senses the voltage or current in the bit line BL corresponding to a target memory cell transistor to determine whether data stored in the target memory cell transistor is “0” or “1”. For example, the sense amplifier portion SA includes a transistor TR1 that is a p-channel MOS transistor, transistors TR2 to TR9 that are n-channel MOS transistors, and a capacitor C10.

One end of the transistor TRI is connected to a power supply line, and the other end of the transistor TRI is connected to the transistor TR2. A gate of the transistor TRI is connected to a node INV in the latch circuit SDL. One end of the transistor TR2 is connected to the transistor TR1, and the other end of the transistor TR2 is connected to a node COM. A signal BLX is input into a gate of the transistor TR2. One end of the transistor TR3 is connected to the node COM, and the other end of the transistor TR3 is connected to the transistor TR4. A signal BLC is input into a gate of the transistor TR3. The transistor TR4 is a high-breakdown voltage MOS transistor. One end of the transistor TR4 is connected to the transistor TR3. The other end of the transistor TR4 is connected to the corresponding bit line BL. A signal BLS is input into a gate of the transistor TR4.

One end of the transistor TR5 is connected to the node COM, and the other end of the transistor TR5 is connected to a node SRC. A gate of the transistor TR5 is connected to the node INV. One end of the transistor TR6 is connected between the transistor TR1 and the transistor TR2, and the other end of the transistor TR6 is connected to a node SEN. A signal HLL is input into a gate of the transistor TR6. One end of the transistor TR7 is connected to the node SEN, and the other end of the transistor TR7 is connected to the node COM. A signal XXL is input into a gate of the transistor TR7.

One end of the transistor TR8 is grounded, and the other end of the transistor TR8 is connected to the transistor TR9. A gate of the transistor TR8 is connected to the node SEN. One end of the transistor TR9 is connected to the transistor TR8, and the other end of the transistor TR9 is connected to the bus LBUS. A signal STB is input into a gate of the transistor TR9. One end of the capacitor C10 is connected to the node SEN. A clock CLK is input into the other end of the capacitor C10.

For example, the signals BLX, BLC, BLS, HLL, XXL, and STB are generated by the sequencer 24. For example, the voltage VDD that is an internal power supply voltage of the semiconductor memory device 2 is applied to the power supply line connected to one end of the transistor TR1, and the voltage VSS that is a ground voltage of the semiconductor memory device 2 is applied to the node SRC.

The latch circuits SDL, ADL, BDL, CDL, and XDL temporarily store the read data. The latch circuit XDL is connected to the input-output circuit 22 and is used for inputting and outputting data between the sense amplifier unit SAU and the input-output circuit 22. By storing the read data in the latch circuit XDL, the read data enters a state where the read data can be output to the memory controller 1 from the input-output circuit 22. For example, data read by the sense amplifier unit SAU is stored in any of the latch circuits ADL, BDL, and CDL and is then transmitted to the latch circuit XDL and output to the input-output circuit 22 from the latch circuit XDL. For example, data input into the input-output circuit 22 from the memory controller 1 is transmitted to the latch circuit XDL from the input-output circuit 22 and transmitted to any of the latch circuits ADL, BDL, and CDL from the latch circuit XDL.

For example, the latch circuit SDL includes inverters IV11 and IV12 and transistors TR13 and TR14 that are n-channel MOS transistors. An input node of the inverter IV11 is connected to a node LAT. An output node of the inverter IV11 is connected to the node INV. An input node of the inverter IV12 is connected to the node INV. An output node of the inverter IV12 is connected to the node LAT. One end of the transistor TR13 is connected to the node INV, and the other end of the transistor TR13 is connected to the bus LBUS. A signal ST1 is input into a gate of the transistor TR13. One end of the transistor TR14 is connected to the node LAT, and the other end of the transistor TR14 is connected to the bus LBUS. A signal STL is input into a gate of the transistor TR14. For example, data stored in the node LAT corresponds to data stored in the latch circuit SDL. Data stored in the node INV corresponds to inverted data of the data stored in the node LAT. For example, circuit configurations of the latch circuits ADL, BDL, CDL, and XDL are the same as a circuit configuration of the latch circuit SDL and thus, will not be described.

### 1.6 Threshold Distribution of Memory Cell Transistor of Second Block Group

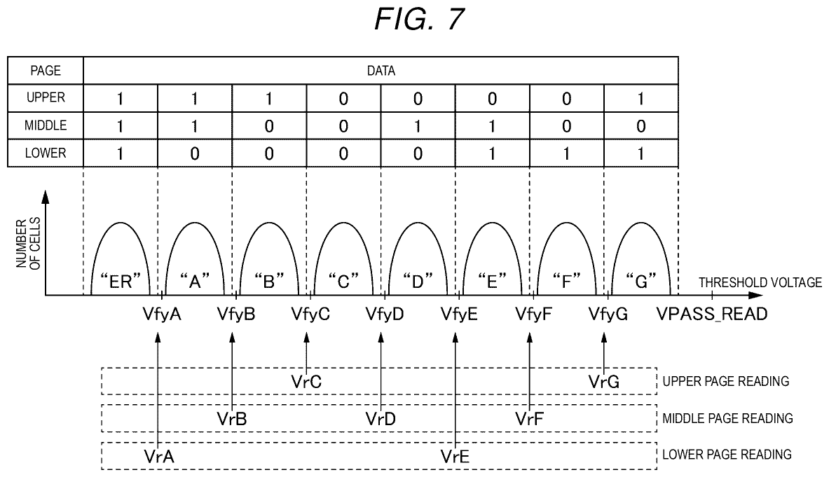

FIG. 7 is a diagram schematically illustrating a threshold distribution and the like of the memory cell transistor MTb of the second block group 212. The diagram in the middle part of FIG. 7 represents a correspondence relationship between a threshold voltage of the memory cell transistor MTb (a horizontal axis) and the number of memory cell transistors MTb (a vertical axis).

When the TLC method is employed as in the present embodiment, a plurality of memory cell transistors MTb form eight threshold distributions as illustrated in the middle part of FIG. 7. These eight threshold distributions (write levels) will be referred to as a level “ER”, a level “A”, a level “B”, a level “C”, a level “D”, a level “E”, a level “F”, and a level “G” in order of increasing threshold voltage.

The table in the upper part of FIG. 7 represents an example of data assigned in accordance with each level of the threshold voltage. As illustrated in the table, for example, different pieces of 3-bit data shown below are assigned to the level “ER”, the level “A”, the level “B”, the level “C”, the level “D”, the level “E”, the level “F”, and the level “G”.

Level “ER”: “111” (“lower bit/middle bit/upper bit”)
Level “A”: “011”
Level “B”: “001”
Level “C”: “000”
Level “D”: “010”
Level “E”: “110”
Level “F”: “100”
Level “G”: “101”

The threshold voltage of the memory cell transistor MTb in the present embodiment may have one of eight candidate levels set in advance, and data is assigned in accordance with each candidate level, as described above.

A verification voltage used in the write operation is set between each pair of threshold distributions adjacent to each other. Specifically, verification voltages VfyA, VfyB, VfyC, VfyD, VfyE, VfyF, and VfyG are set in accordance with the level “A”, the level “B”, the level “C”, the level “D”, the level “E”, the level “F”, and the level “G”, respectively.

The verification voltage VfyA is set between the maximum threshold voltage in the level “ER” and the minimum threshold voltage in the level “A”. When the verification voltage VfyA is applied to the word line WL, the memory cell transistor MTb of which the threshold voltage is included in the level “ER” enters an ON state, and the memory cell transistor MTb of which the threshold voltage is included in a threshold distribution of the level “A” or higher enters an OFF state, among the memory cell transistors MTb connected to the word line WL.

Other verification voltages VfyB, VfyC, VfyD, VfyE, VfyF, and VfyG are also set in the same manner as the verification voltage VfyA. The verification voltage VfyB is set between the level “A” and the level “B”. The verification voltage VfyC is set between the level “B” and the level “C”. The verification voltage VfyD is set between the level “C” and the level “D”. The verification voltage VfyE is set between the level “D” and the level “E”. The verification voltage VfyF is set between the level “E” and the level “F”. The verification voltage VfyG is set between the level “F” and the level “G”.

For example, the verification voltage VfyA may be set to 0.8 V. The verification voltage VfyB may be set to 1.6 V. The verification voltage VfyC may be set to 2.4 V. The verification voltage VfyD may be set to 3.1 V. The verification voltage VfyE may be set to 3.8 V. The verification voltage VfyF may be set to 4.6 V. The verification voltage VfyG may be set to 5.6 V. However, the verification voltages VfyA, VfyB, VfyC, VfyD, VfyE, VfyF, and VfyG are not limited to this and, for example, may be appropriately set stepwise within a range of 0 V to 7.0 V.

A read voltage used in the read operation is set between each pair of threshold distributions adjacent to each other. The term “read voltage” means a voltage applied to the word line WL connected to the memory cell transistor MTb to be read, that is, the selected word line, during the read operation. In the read operation, data is determined based on a determination result of whether the threshold voltage of the memory cell transistor MTb to be read is higher than the applied read voltage.

Specifically, as schematically illustrated in the drawing in the lower part of FIG. 7, the read voltage VrA for determining whether the threshold voltage of the memory cell transistor MTb is included in the level “ER” or included in the level “A” or higher is set between the maximum threshold voltage in the level “ER” and the minimum threshold voltage in the level “A”.

Other read voltages VrB, VrC, VrD, VrE, VrF, and VrG are set in the same manner as the read voltage VrA. The read voltage VrB is set between the level “A” and the level “B”. The read voltage VrC is set between the level “B” and the level “C”. The read voltage VrD is set between the level “C” and the level “D”. The read voltage VrE is set between the level “D” and the level “E”. The read voltage VrF is set between the level “E” and the level “F”. The read voltage VrG is set between the level “F” and the level “G”.

A read pass voltage VPASS_READ is set to a voltage higher than the maximum threshold voltage of the highest threshold distribution (for example, the level “G”). The memory cell transistor MTb of which the read pass voltage VPASS_READ is applied to a gate enters the ON state regardless of the stored data.

For example, the verification voltages VfyA, VfyB, VfyC, VfyD, VfyE, VfyF, and VfyG are set to voltages higher than the read voltages VrA, VrB, VIC, VrD, VrE, VrF, and VrG, respectively. That is, the verification voltages VfyA, VfyB, VfyC, VfyD, VfyE, VfyF, and VfyG are set to voltages near lower tails of the threshold distributions of the level “A”, level “B”, level “C”, level “D”, level “E”, level “F”, and level “G”, respectively.

While each memory cell transistor MTb of the second block group 212 is illustrated as storing 3-bit data in the description of the semiconductor memory device 2 according to the present embodiment, the present disclosure is not limited to this. For example, the semiconductor memory device 2 may be configured such that each memory cell transistor MTb of the second block group 212 stores 2-bit data or 4-bit data or more.

### 1.7 Write Operation of Memory Cell Transistor of Second Block Group

Next, a write operation of the memory cell transistor MTb of the second block group 212 of the memory cell array 21 will be described.

The semiconductor memory device 2 repeats execution of a program loop operation in the write operation of the memory cell transistor MTb. Each program loop operation includes a program operation and a verification operation. The semiconductor memory device 2 increases the threshold voltage of the memory cell transistor MTb of the second block group 212 to a target voltage (hereinafter, referred to as a target level) by repeating the program loop operation.

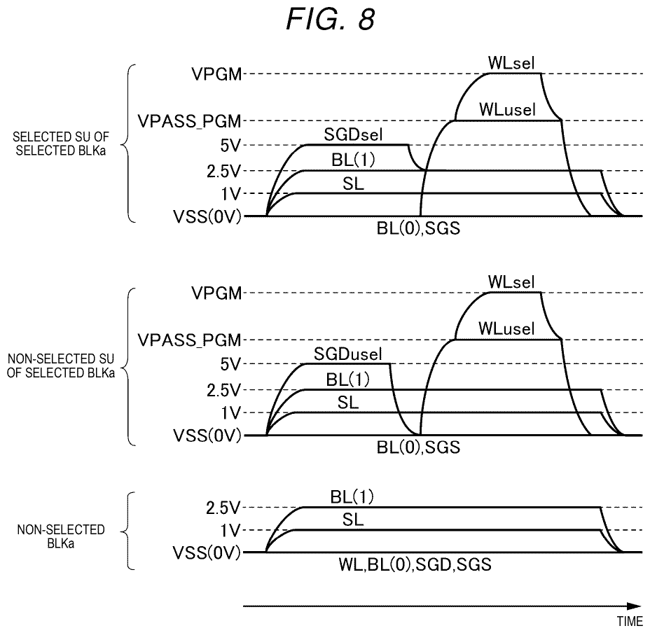

In each program loop operation, the sequencer 24 executes the program operation before the verification operation. FIG. 8 illustrates a change in a voltage of each wire during the program operation. In the program operation, the sense amplifier 28 changes a voltage of each bit line BL in accordance with program data. For example, the ground voltage VSS (0 V) is applied as a level “L” to the bit line BL connected to the memory cell transistor MT to be programmed (of which the threshold voltage is to be increased). For example, 2.5 V is applied as a level “H” to the bit line BL connected to the memory cell transistor MT not to be programmed (of which the threshold voltage is to be maintained). The former bit line BL is denoted by “BL (0)” in FIG. 8. The latter bit line BL is denoted by “BL (1)” in FIG. 8.

The row decoder 271 is able to select any block BLKb and any string unit SU to be subjected to the write operation. More specifically, for example, 5 V is applied to the select gate line SGD (a selected select gate line SGDₛₑₗ) in the selected string unit SU from the voltage generation circuit 26 through the row decoder 271. Accordingly, the select transistor ST1 enters the ON state. Meanwhile, for example, the voltage VSS is applied to the select gate line SGS from the voltage generation circuit 26 through the row decoder 271. Accordingly, the select transistor ST2 enters the OFF state.

For example, a voltage of 5 V is applied to the select gate line SGD (a non-selected select gate line SGDᵤₛₑₗ) of a non-selected string unit SU in the selected block BLKb from the voltage generation circuit 26 through the row decoder 271. Accordingly, the select transistor ST1 enters the ON state. The select gate line SGS is connected in common in the string unit SU provided in each block BLKb. Accordingly, the select transistor ST2 in the non-selected string unit SU also enters the OFF state.

For example, the voltage VSS is applied to the select gate line SGD and the select gate line SGS in a non-selected block BLKb from the voltage generation circuit 26 through the row decoder 271. Accordingly, the select transistor ST1 and the select transistor ST2 enter the OFF state.

The source line SL is set to have a higher voltage than a voltage of the select gate line SGS. For example, the voltage is 1 V.

Then, for example, a voltage of the selected select gate line SGDₛₑₗ in the selected block BLKb is set to 2.5 V. This voltage is a voltage that can switch ON the select transistor ST1 corresponding to the bit line BL (0) to which 0 V is applied, and can CUT OFF the select transistor ST1 corresponding to the bit line BL (1) to which 2.5 V is applied in the above example. Accordingly, in the selected string unit SU, the select transistor ST1 corresponding to the bit line BL (0) is switched ON, and the select transistor ST1 corresponding to the bit line BL (1) to which 2.5 V is applied is CUT OFF. Meanwhile, for example, a voltage of the non-selected select gate line SGDᵤₛₑₗ is set to the voltage VSS. Accordingly, in the non-selected string unit SU, the select transistor ST1 is CUT OFF regardless of voltages of the bit line BL (0) and the bit line BL (1).

The row decoder 271 is able to select any word line WL to be subjected to the write operation in the selected block BLKb. For example, a voltage VPGM is applied to the word line WL (a selected word line WLₛₑₗ) to be subjected to the write operation from the voltage generation circuit 26 through the row decoder 271. Meanwhile, for example, a voltage VPASS_PGM is applied to other word lines WL (non-selected word lines WLᵤₛₑₗ) from the voltage generation circuit 26 through the row decoder 271. The voltage VPGM is a high voltage for injecting electrons into the charge storage layer 336 through a tunneling phenomenon. The voltage VPASS_PGM is a voltage that switches ON the memory cell transistor MT connected to the word line WL and that does not change the threshold voltage. The voltage VPGM is a higher voltage than VPASS_PGM.

In the NAND string NS corresponding to the bit line BL (0) to be programmed, the select transistor ST1 enters the ON state. Thus, a channel voltage of the memory cell transistor MT connected to the selected word line WLₛₑₗ changes to 0 V. Consequently, a difference in voltage between a control gate and a channel is increased, and electrons are injected into the charge storage layer 336. Thus, the threshold voltage of the memory cell transistor MT is increased.

In the NAND string NS corresponding to the bit line BL (1) not to be programmed, the select transistor ST1 enters a CUT OFF state. Thus, the channel of the memory cell transistor MT connected to the selected word line WLₛₑₗ is in an electrically floating state, and the channel voltage is increased to a voltage close to the voltage VPGM through capacitive coupling with the word line WL and the like. Consequently, the difference in the voltage between the control gate and the channel is decreased, and electrons are not injected into the charge storage layer 336. Thus, the threshold voltage of the memory cell transistor MT is maintained. More precisely, a transition of a threshold distribution level to a higher distribution level does not occur.

When the program operation is finished, the sequencer 24 executes the verification operation.

The verification operation is a read operation of verifying whether the threshold voltage of a selected memory cell transistor MTb reaches a target threshold voltage. For example, in each program loop operation, the sequencer 24 executes the read operation for the memory cell transistor MTb to be programmed using a predetermined verification voltage.

In each verification operation, not only one verification voltage but also a plurality of verification voltages may be used. In this case, for example, the sequencer 24 sequentially executes the read operation using the plurality of verification voltages.

In the verification operation, the sense amplifier unit SAU determines whether the threshold voltage of the selected memory cell transistor MTb is higher than the verification voltage supplied to the selected word line WL based on the voltage of the bit line BL. Each sense amplifier unit SAU makes a determination of “verification passed” for the selected memory cell transistor MTb for which the threshold voltage of the selected memory cell transistor Mtb is determined to be higher than the verification voltage. Meanwhile, each sense amplifier unit SAU makes a determination of “verification failed” for the selected memory cell transistor MTb for which the threshold voltage of the selected memory cell transistor Mtb is lower than or equal to the verification voltage. Each sense amplifier unit SAU stores a verification result described above in any latch circuit in the sense amplifier unit SAU. When the verification operation is completed, the sequencer 24 sets each selected memory cell transistor MTb to the memory cell transistor MTb to be programmed or the memory cell transistor MTb inhibited from being programmed, based on a result of the verification operation and starts the subsequent program loop operation.

### 1.8 Write Operation of Memory Cell Transistor of First Block Group

Next, a write operation of the memory cell transistor MTa of the first block group 211 of the memory cell array 21 will be described. Hereinafter, an example in which the semiconductor memory device 2 operates as illustrated in FIG. 5A, that is, the write operation is performed using the NOP method, will be described.

As described above, the memory cell transistor MTa of the first block group 211 employs the SLC method. That is, the memory cell transistor MTa forms two levels of threshold distributions. The semiconductor memory device 2 performs a write operation including a precharge operation and the program operation for the memory cell transistor MTa. This write operation does not include the verification operation. The precharge operation is an operation of charging the channel of the memory cell transistor MTa before the program operation in order to stabilize an initial voltage of the channel.

The semiconductor memory device 2 performs the write operation on the memory cell transistor MTa of the block BLKa₂ₓ₊₁ of the first block group 211 via the odd-numbered row decoder 271 during a period in which the even-numbered row decoder 270 performs the write operation on the memory cell transistor MTa of the block BLKa₂ₓ of the first block group 211. Here, x=0, 1, . . . , p is established. In the semiconductor memory device 2 according to the present embodiment, in performing the write operation of the first block group 211, a speed of the write operation is improved by causing the period of the write operation of the block BLKa₂ₓ to overlap with a period of the write operation of the block BLKa₂ₓ₊₁.

Hereinafter, the block BLKa₂ₓ of the first block group 211 will be referred to as an “even-numbered block BLKa₂ₓ”, and the block BLKa₂ₓ₊₁ of the first block group 211 will be referred to as an “odd-numbered block BLKa₂ₓ₊₁”. The word line WL corresponding to the even-numbered block BLKa₂ₓ will be referred to as a “word line WL2x”, and the word line WL corresponding to the odd-numbered block BLKa₂ₓ₊₁ will be referred to as a “word line WL₂ₓ₊₁”. The memory cell transistor MTa of the even-numbered block BLKa₂ₓ will be referred to as a “memory cell transistor MTa₂ₓ”, and the memory cell transistor MTa of the odd-numbered block BLKa₂ₓ₊₁ will be referred to as a “memory cell transistor MTa₂ₓ₊₁”. In the present embodiment, the even-numbered block BLKa₂ₓ is an example of a first block, and the odd-numbered block BLKa₂ₓ₊₁ is an example of a second block. The word line WL₂ₓ is an example of a first word line, and the word line WL₂ₓ₊₁ is an example of a second word line. The memory cell transistor MTa₂ₓ is an example of a first memory cell transistor, and the memory cell transistor MTₐ₂ₓ₊₁ is an example of a second memory cell transistor.

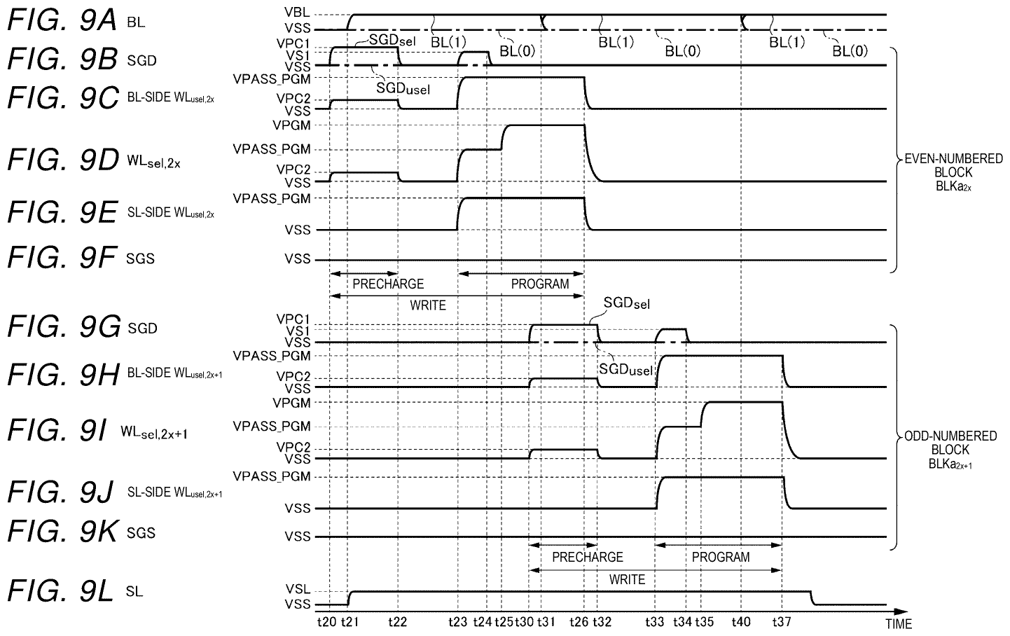

FIGS. 9A to 9L illustrate a change in the voltage of each wire in the write operation of each of the even-numbered block BLKa₂ₓ and the odd-numbered block BLKa₂ₓ₊₁ of the first block group 211.

As illustrated in FIGS. 9A to 9L, the semiconductor memory device 2 executes the precharge operation on the even-numbered block BLKa₂ₓ during a period from time t20 to time t22. Specifically, at time t20, the even-numbered row decoder 270 selects an even-numbered block BLKa₂ₓ (a selected even-numbered block BLKa₂ₓ) from a plurality of even-numbered blocks BLKa₂ₓ of the first block group 211. The even-numbered row decoder 270 selects a string unit SU₂ₓ (a selected string unit SU₂ₓ) from the plurality of string units SU (string units SU₂ₓ) of the selected even-numbered block BLKa₂ₓ. The even-numbered row decoder 270 applies a voltage VPC1 (>VSS) to the selected select gate line SGDₛₑₗ in the selected string unit SU₂ₓ. For example, the voltage VPC1 is 5 V. Accordingly, the select transistor ST1 corresponding to the selected string unit SU₂ₓ enters the ON state.

Meanwhile, at time t20, the even-numbered row decoder 270 applies the voltage VSS to the selected select gate line SGD (the non-selected select gate line SGDᵤₛₑₗ) of the string unit SU₂ₓ (the non-selected string unit SU₂ₓ) that is not the selected string unit SU₂ₓ, among the plurality of string units SU₂ₓ. Accordingly, the select transistor ST1 corresponding to the non-selected string unit SU₂ₓ enters the OFF state.

At time t20, the voltage VSS is applied to the select gate line SGS of the even-numbered block BLKa₂ₓ. Accordingly, the select transistor ST2 enters the OFF state.

At time t20, the even-numbered row decoder 270 applies a voltage VPC2 (>VSS) to a selected word line WL_{sel,2x} corresponding to the memory cell transistor MTa₂ₓ to be programmed among the selected even-numbered blocks BLKa₂ₓ, and to a BL-side non-selected word line WL_{usel,2x} positioned closer to the bit line BL than the selected word line WL_{sel,2x}. For example, the voltage VPC2 is 2 V. The even-numbered row decoder 270 applies the voltage VSS to an SL-side non-selected word line WL_{usel,2x} positioned closer to the source line SL than the selected word line WL_{sel,2x}. When the selected word line WL_{sel,2x} is referred to as a word line WL a, the BL-side non-selected word line WL_{usel,2x} corresponds to word lines WLa. 1 to WL7, and the SL-side non-selected word line WL_{usel, 2x} corresponds to word lines WL₀ to WL_{α-1}.

At time t21, the voltage generation circuit 26 applies a voltage VSL (>VSS) to the source line SL. For example, the voltage VSL is 1 V. At time t21, the sense amplifier 28 applies a voltage VBL to the bit line BL (1) corresponding to the memory cell transistor MTa₂ₓ not to be programmed. Accordingly, in the selected string unit SU₂ₓ in which the select transistor ST1 is in the ON state, the voltage VBL is applied from the bit line BL (1) to a channel area corresponding to the selected word line WL_{sel,2x} and the BL-side non-selected word line WL_{usel,2x} positioned closer to the bit line BL than the selected word line WL_{sel,2x} in the memory pillar MP (a memory pillar MPa₂ₓ) of the NAND string NS including the memory cell transistor MTa₂ₓ not to be programmed, and a voltage of the channel area becomes equal to the voltage VBL. At time t21, the sense amplifier 28 applies the voltage VSS to the bit line BL (0) corresponding to the memory cell transistor MTa₂ₓ to be programmed. Accordingly, in the selected string unit SU₂ₓ in which the select transistor ST1 is in the ON state, the voltage VSS is applied from the bit line BL (0) to a channel area corresponding to the selected word line WL_{sel,2x} and the BL-side non-selected word line WL_{usel,2x} positioned closer to the bit line BL than the selected word line WL_{sel,2x} in the memory pillar MPa₂ₓ of the NAND string NS including the memory cell transistor MTa₂ₓ to be programmed in the selected string unit SU₂ₓ and a voltage of the channel area becomes equal to the voltage VSS.

Performing the precharge operation can stabilize the initial voltage of the channel of the memory cell transistor MTa₂ₓ of the selected string unit SU₂ₓ before the program operation starts. Thus, for example, so-called program data sweep that is erroneous writing on the memory cell transistor MTa₂ₓ not to be programmed is unlikely to occur.

At time t22, the even-numbered row decoder 270 decreases the voltage of the selected select gate line SGDₛₑₗ in the selected string unit SU₂ₓ of the selected even-numbered block BLKa₂ₓ to the voltage VSS from the voltage VPC1. The even-numbered row decoder 270 decreases the voltages of the selected word line WL_{sel,2x} and the BL-side non-selected word line WL_{usel,2x} of the selected even-numbered block BLKa₂ₓ to the voltage VSS from the voltage VPC2. Accordingly, the voltage VSS is applied to all word lines WL₂ₓ of the selected even-numbered block BLKa₂ₓ.

Next, the semiconductor memory device 2 executes the program operation on the selected even-numbered block BLKa₂ₓ during a period from time t23 to time t26. Specifically, at time t23, the even-numbered row decoder 270 applies a voltage VS1 (>VSS) to the selected select gate line SGDₛₑₗ of the selected string unit SU₂ₓ of the selected even-numbered block BLKa₂ₓ. The voltage VS1 is a voltage that can cause the select transistor ST1 corresponding to the bit line BL (0) to which the voltage VSS is applied to enter the ON state and cause the select transistor STI corresponding to the bit line BL (1) to which the voltage VBL is applied to enter the OFF state. For example, the voltage VS1 is 1.5 V to 2.5 V. When the select transistor ST1 corresponding to the bit line BL (1) enters the OFF state, a channel area of the memory pillar MPa₂ₓ corresponding to the bit line BL (1) enters a so-called floating state that is a state of being electrically insulated from both of the bit line BL (1) and the source line SL.

At time t23, the even-numbered row decoder 270 applies the voltage VPASS_PGM to the selected word line WL_{sel,2x}, the BL-side non-selected word line WL_{usel,2x}, and the SL-side non-selected word line WL_{usel,2x} of the selected even-numbered block BLKa₂ₓ. At this point, a voltage of the channel area of the memory pillar MPa₂ₓ corresponding to the bit line BL (1) in the floating state is increased to a voltage equal to the voltage VPASS_PGM through capacitive coupling between the channel area of the memory pillar MPA₂ₓ and the word line WL₂ₓ.

At time t24, the even-numbered row decoder 270 decreases the voltage of the selected select gate line SGDₛₑₗ in the selected string unit SU₂ₓ of the selected even-numbered block BLKa₂ₓ to the voltage VSS from the voltage VS1. Accordingly, a channel area of the memory pillar MPa₂ₓ corresponding to the bit line BL (0) also enters the floating state of being electrically insulated from both of the bit line BL (0) and the source line SL. Accordingly, a voltage of the channel area of the memory pillar MPa₂ₓ corresponding to the bit line BL (0) in the floating state is maintained at a voltage equal to the voltage VSS.

At time t25, the even-numbered row decoder 270 maintains the voltage of the non-selected word line WL_{usel,2x} of the selected even-numbered block BLKa₂ₓ at the voltage VPASS_PGM and increases the voltage of the selected word line WL_{sel,2x} to the voltage VPGM from the voltage VPASS_PGM. At this point, the voltage of the channel area of the memory pillar MPa₂ₓ corresponding to the bit line BL (0) is slightly increased. However, since a state where the voltage VPASS_PGM is applied to the non-selected word line WL_{usel,2x} is maintained, an increase in a channel voltage of the entire memory pillar MPa₂ₓ of the NAND string NS corresponding to the bit line BL (0) is reduced to a sufficiently low level. Thus, since a difference in voltage can be secured between a gate of the memory cell transistor MTa₂ₓ corresponding to the selected word line WL_{sel,2x} and the channel area of the memory pillar MPa₂ₓ, charges are injected into the charge storage layer 336 of the memory cell transistor MTa₂ₓ corresponding to the selected word line WL_{sel,2x} from the channel area, and the threshold voltage of the memory cell transistor MTa₂ₓ is increased. That is, in the NAND string NS corresponding to the bit line BL (0), the memory cell transistor MTa₂ₓ corresponding to the selected word line WL_{sel,2x} is programmed.

Meanwhile, in the NAND string NS corresponding to the bit line BL (1), a difference in voltage generated between the channel area of the memory pillar MPa₂ₓ and the gate of the memory cell transistor MTa₂ₓ corresponding to the selected word line WL_{sel,2x} is small. Thus, charges are not injected into the charge storage layer 336 of the memory cell transistor MTa₂ₓ from the channel area. That is, in the NAND string NS corresponding to the bit line BL (1), the memory cell transistor MTa₂ₓ corresponding to the selected word line WL_{sel,2x} is not programmed.

At time t26, the even-numbered row decoder 270 decreases the voltage of each of the selected word line WL_{sel,2x} and the non-selected word line WL_{usel,2x} to the voltage VSS. Accordingly, the program operation of the selected even-numbered block BLKa₂ₓ is finished.

Meanwhile, during the period from time t23 to time t26, that is, during a period in which the program operation of the even-numbered row decoder 270 is performed, the odd-numbered row decoder 271 executes the precharge operation on the odd-numbered block BLKa₂ₓ₊₁. This precharge operation is the same as or similar to the precharge operation performed on the even-numbered block BLKa₂ₓ during the period from time t20 to time t22.

That is, at time t30, the odd-numbered row decoder 271 selects an odd-numbered block BLKa₂ₓ₊₁ (a selected odd-numbered block BLKa₂ₓ₊₁) from the plurality of blocks BLK of the first block group 211. The odd-numbered row decoder 271 selects a string unit SU₂ₓ₊₁ (a selected string unit SU₂ₓ₊₁) from the plurality of string units SU (string units SU₂ₓ₊₁) of the selected odd-numbered block BLKa₂ₓ₊₁. The odd-numbered row decoder 271 applies the voltage VPC1 to the selected select gate line SGDₛₑₗ in the selected string unit SU₂ₓ₊₁. The odd-numbered row decoder 271 applies the voltage VSS to the selected select gate line SGD (the non-selected select gate line SGDᵤₛₑₗ) of the string unit SU₂ₓ₊₁ (the non-selected string unit SU₂ₓ₊₁) that is not the selected string unit SU₂ₓ₊₁, among the plurality of string units SU₂ₓ₊₁. At time t30, the odd-numbered row decoder 271 applies the voltage VPC2 to a selected word line WL_{sel,2x+1} corresponding to the memory cell transistor MTa (the memory cell transistor MTa₂ₓ₊₁) to be programmed among the selected odd-numbered blocks BLKa₂ₓ₊₁, and to a BL-side non-selected word line WL_{usel,2x+1} positioned closer to the bit line BL than the selected word line WL_{sel,2x+1}. The odd-numbered row decoder 271 applies the voltage VSS to an SL-side non-selected word line WL_{usel,2x+1} positioned closer to the source line SL than the selected word line WLₛₑₗ,2x+1.

At time t31, the sense amplifier 28 applies the voltage VBL to the bit line BL (1) corresponding to the memory cell transistor MTₐ₂ₓ₊₁ not to be programmed. The sense amplifier 28 applies the voltage VSS to the bit line BL (0) corresponding to the memory cell transistor MTₐ₂ₓ₊₁ to be programmed.

At time t32, the odd-numbered row decoder 271 decreases the voltage of the selected select gate line SGDₛₑₗ in the selected string unit SU₂ₓ₊₁ of the selected odd-numbered block BLKa₂ₓ₊₁ to the voltage VSS from the voltage VPC1. The odd-numbered row decoder 271 decreases the voltages of the selected word line WL_{sel,2x+1} and the BL-side non-selected word line WL_{usel,2x+1} of the selected odd-numbered block BLKa₂ₓ₊₁ to the voltage VSS from the voltage VPC2. Accordingly, the voltage VSS is applied to all word lines WL₂ₓ₊₁ of the selected odd-numbered block BLKa₂ₓ₊₁. In accordance with the above, the precharge operation is performed in the odd-numbered block BLKa₂ₓ₊₁ during a period from time t30 to time t32.

Next, during a period from time t33 to time t36, the odd-numbered row decoder 271 executes the program operation on the odd-numbered block BLKa₂ₓ₊₁. This program operation is the same as or similar to the program operation performed on the even-numbered block BLKa₂ₓ during the period from time t23 to time t26.

That is, at time t33, the odd-numbered row decoder 271 applies the voltage VS1 to the selected select gate line SGDₛₑₗ of the selected string unit SU₂ₓ₊₁ of the selected odd-numbered block BLKa₂ₓ₊₁. At time t33, the odd-numbered row decoder 271 applies the voltage VPASS_PGM to the selected word line WL_{sel,2x+1}, the BL-side non-selected word line WL_{usel,2x+1}, and the SL-side non-selected word line WL_{usel,2x+1} of the selected odd-numbered block BLKa₂ₓ₊₁. At time t34, the odd-numbered row decoder 271 decreases the voltage of the selected select gate line SGDₛₑₗ in the selected string unit SU₂ₓ₊₁ of the selected odd-numbered block BLKa₂ₓ₊₁ to the voltage VSS from the voltage VS1. Accordingly, a channel area of the memory pillar MPa₂ₓ₊₁ corresponding to the bit line BL (0) enters the floating state of being electrically insulated from both of the bit line BL (0) and the source line SL. Next, at time t35, the odd-numbered row decoder 271 maintains the voltage of the non-selected word line WL_{usel,2x+1} of the selected odd-numbered block BLKa₂ₓ₊₁ at the voltage VPASS_PGM and increases the voltage of the selected word line WL_{sel,2x+1} to the voltage VPGM from the voltage VPASS_PGM. Accordingly, in the NAND string NS corresponding to the bit line BL (0), the memory cell transistor MTₐ₂ₓ₊₁ corresponding to the selected word line WL_{sel,2x+1} is programmed. At time t36, the odd-numbered row decoder 271 applies the voltage VSS to the selected word line WL_{sel,2x+1} and the non-selected word line WL_{usel,2x+1}. Accordingly, the program operation of the selected odd-numbered block BLKa₂ₓ₊₁ is finished. In accordance with the above, the program operation is performed in the odd-numbered block BLKa₂ₓ₊₁ during a period from time t30 to time t36 in the semiconductor memory device 2 according to the present embodiment.

During the period from time t30 to time t36, that is, during a period in which the odd-numbered row decoder 271 performs the write operation of the odd-numbered block BLKa₂ₓ₊₁, the semiconductor memory device 2 may perform the write operation in an even-numbered block BLKa₂ₓ different from the even-numbered block BLKa₂ₓ subjected to the write operation during the period from time t20 to time t26. While the timing charts illustrated in FIGS. 9A to 9L illustrate application of the voltage VBL to the bit line BL (1) and application of the voltage VSS to the bit line BL (0) at time t40, this illustrates a change in the voltage of the bit line BL when the write operation is performed in the other even-numbered block BLKa₂ₓ. When the even-numbered row decoder 270 performs the write operation of the even-numbered block BLKa₂ₓ during the period in which the odd-numbered row decoder 271 performs the write operation of the odd-numbered block BLKa₂ₓ₊₁, the odd-numbered block BLKa₂ₓ₊₁ is an example of the first block, and the even-numbered block BLKa₂ₓ is an example of the second block.

### 1.9 Operation Example of Memory Cell Array

Next, an operation example of the first block group 211 according to the present embodiment will be described.

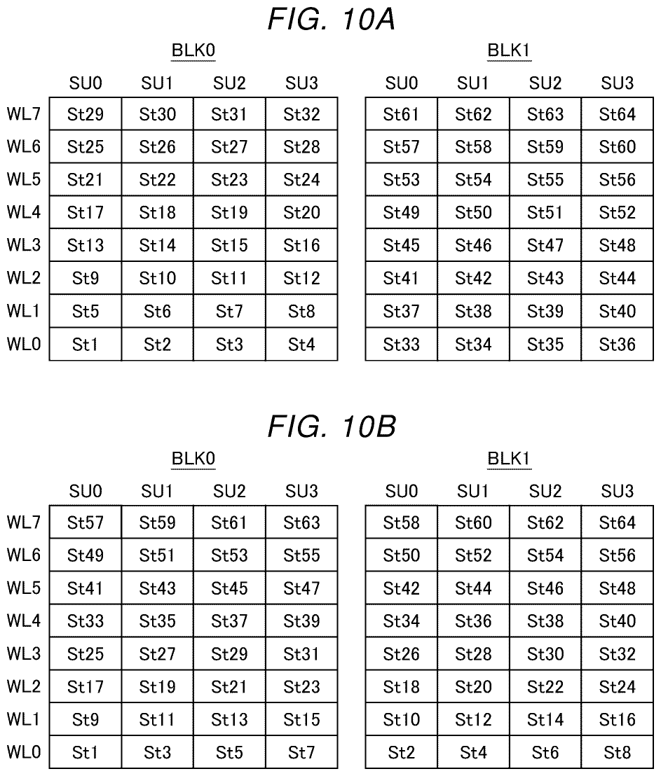

FIG. 10A illustrates a write order of the memory cell transistors MT as numbers when writing of a block BLK0 and a block BLK1 of the first block group 211 in a semiconductor memory device according to a reference example.

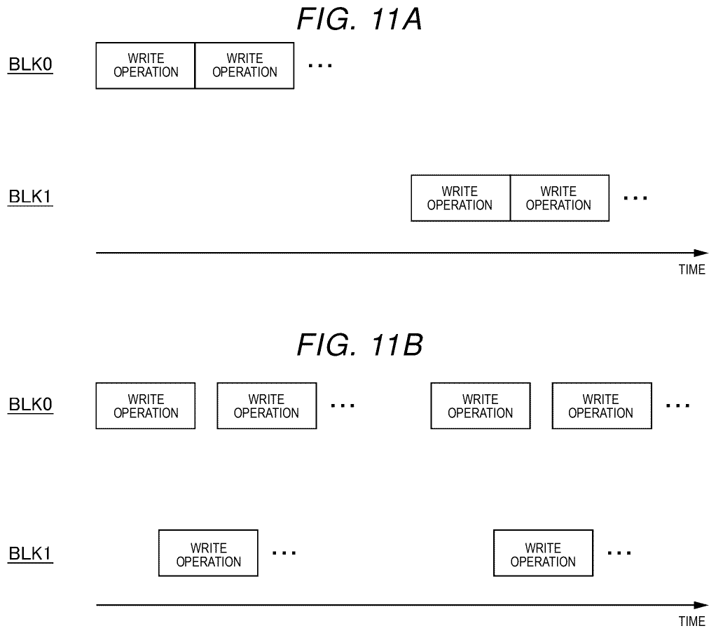

In the semiconductor memory device according to the reference example, writing of the block BLK1 starts after writing of the block BLK0 is completed. In the semiconductor memory device according to the reference example, for example, the word line WL0 is selected as the selected word line WLₛₑₗ, and writing is performed on the memory cell transistor MT corresponding to the word line WL0 in the string unit SU0 of the block BLK0 (St1). Next, in the semiconductor memory device according to the reference example, writing is performed on the memory cell transistor MT corresponding to the word line WL0 in the string unit SU1 of the block BLK0 (St2). In accordance with the above, writing on each block BLK is performed in the semiconductor memory device according to the reference example, as illustrated in FIG. 11A.

Meanwhile, in the semiconductor memory device 2 according to the present embodiment, the write operation of the memory cell transistor MT of the first block group 211 is performed as illustrated in 1.8. Accordingly, for example, writing of the block BLK0 and the block BLK1 of the first block group 211 is performed as illustrated in FIG. 10B. That is, in the semiconductor memory device 2 according to the present embodiment, as illustrated in FIG. 10B, writing of the memory cell transistor MT corresponding to the word line WL0 in the string unit SU0 of the other block BLK1 is performed (St2) after writing of the memory cell transistor MT corresponding to the word line WL0 in the string unit SU0 of the block BLK0 is performed (St1). Accordingly, as illustrated in FIG. 11B, in the semiconductor memory device 2 according to the present embodiment, writing of the other block BLK1 is performed during a period in which writing of the block BLK0 is performed. That is, a period of the write operation of the block BLK0 overlaps with a period of the write operation of the other block BLK1. Thus, as is understood from comparison between FIG. 11A and FIG. 11B, the semiconductor memory device 2 according to the present embodiment can improve the speed of the write operation, compared to the semiconductor memory device 2 according to the reference example.

### 1.10 Action and Effect of Semiconductor Memory Device

As described above, the semiconductor memory device 2 according to the present embodiment includes the memory cell array 21 and the sequencer 24 (the control circuit). The memory cell array 21 includes the even-numbered block BLKa₂ₓ (the first block) and the odd-numbered block BLKa₂ₓ₊₁ (the second block), each of which includes the plurality of memory cell transistors MT. The sequencer 24 controls the memory cell array 21. The even-numbered block BLKa₂ₓ includes the memory cell transistor MTa₂ₓ (the first memory cell transistor) of which a gate is connected to the word line WL₂ₓ (the first word line). The odd-numbered block BLKa₂ₓ₊₁ includes the memory cell transistor MTₐ₂ₓ₊₁ (the second memory cell transistor) of which a gate is connected to the word line WL₂ₓ₊₁ (the second word line). The sequencer 24 applies the voltage VSS (a first voltage) corresponding to data of “0” to be written into the memory cell transistor MTa₂ₓ to the channel area of the memory cell transistor MTa₂ₓ through the bit line BL (0) and then causes the channel area of the memory cell transistor MTa₂ₓ to enter the floating state. The sequencer 24 executes a first write operation of writing the data of “0” into the memory cell transistor MTa₂ₓ by applying the voltage VPGM (a program voltage) to the word line WL₂ₓ in a state where the channel area of the memory cell transistor MTa₂ₓ is in the floating state. The sequencer 24 executes a second write operation of writing data into the memory cell transistor MTₐ₂ₓ₊₁ during a period before application of the voltage VPGM to the word line WL₂ₓ is finished after causing the memory cell transistor MTa₂ₓ to enter the floating state, that is, during the period from the time t23 to the time t26 illustrated in FIGS. 9A to 9L.

According to this configuration, writing of the odd-numbered block BLKa₂ₓ₊₁ starts during a period in which writing is performed in the even-numbered block BLKa₂ₓ. Thus, the speed of the write operation can be improved.

The even-numbered block BLKa₂ₓ further includes the select transistor ST1 (a first select transistor) provided between the memory cell transistor MTa₂ₓ and the bit line BL. The word line WL₂ₓ includes the selected word line WL_{sel,2x} (a first selected word line) and the non-selected word line WL_{usel,2x} (a first non-selected word line). The sequencer 24 executes the program operation (a first program operation) as the write operation of the even-numbered block BLKa₂ₓ. The sequencer 24, in the program operation of the even-numbered block BLKa₂ₓ, applies the voltage VSS to the channel area of the memory cell transistor MTa₂ₓ from the bit line BL (0) by switching ON the select transistor ST1 in a state where the voltage VSS is applied to the bit line BL (0), and causes the channel area of the memory cell transistor MTa₂ₓ to enter the floating state by switching OFF the select transistor ST1 in a state where the voltage VSS is applied to the channel area of the memory cell transistor MTa₂ₓ. Then, the sequencer 24 applies the voltage VPGM to the selected word line WL_{sel,2x} and applies the voltage VPASS_PGM (a write pass voltage) lower than the voltage VPGM to the non-selected word line WL_{usel,2x}.

The sequencer 24 executes the same program operation (a second program operation) as the write operation of the odd-numbered block BLKa₂ₓ₊₁. At this point, the voltage VSS applied to the bit line BL (0) for programming the memory cell transistor MTₐ₂ₓ₊₁ with the data of “O” is an example of a second voltage. The select transistor ST1 provided between the memory cell transistor MTₐ₂ₓ₊₁ and the bit line BL in the odd-numbered block BLKa₂ₓ₊₁ is an example of a third select transistor. The selected word line WL_{sel,2x+1} is an example of a second selected word line, and the non-selected word line WL_{usel,2x+1} is an example of a second non-selected word line.

According to this configuration, writing of the even-numbered block BLKa₂ₓ and the odd-numbered block BLKa₂ₓ₊₁ can be performed in a state where the channel areas of the memory cell transistors MTa₂ₓ and MTₐ₂ₓ₊₁ are in the floating state.

The sequencer 24 executes the program operation following the precharge operation (a first precharge operation), as the write operation of the even-numbered block BLKa₂ₓ. In the first precharge operation, the sequencer 24 applies the voltage VSS to the bit line BL (0) and applies the voltage VPC2 (a precharge voltage) lower than the voltage VPASS_PGM to the selected word line WL_{sel,2x} and the non-selected word line WL_{usel,2x} in a state where the select transistor ST1 is switched ON. The sequencer 24 also executes the program operation following the precharge operation (a third precharge operation), as the write operation of the odd-numbered block BLKa₂ₓ₊₁.

According to this configuration, the initial voltages of the channels of the memory cell transistors MTa₂ₓ and MTₐ₂ₓ₊₁ before the program operation starts can be stabilized.

The sequencer 24 starts the write operation of the odd-numbered block BLKa₂ₓ₊₁ after causing the channel area of the memory cell transistor MTa₂ₓ to enter the floating state and applying the voltage VPGM to the selected word line WL_{sel,2x}.

According to this configuration, writing of the odd-numbered block BLKa₂ₓ₊₁ can start during the period in which writing is performed in the even-numbered block BLKa₂ₓ.

The semiconductor memory device 2 further includes the even-numbered row decoder 270 (the first row decoder) connected to the word line WL₂ₓ and the odd-numbered row decoder 271 (the second row decoder) connected to the word line WL₂ₓ₊₁. According to this configuration in which the sequencer 24 controls the voltage of the word line WL₂ₓ through the even-numbered row decoder 270 and controls the voltage of the word line WL₂ₓ₊₁ through the odd-numbered row decoder 271, the write operation of the even-numbered block BLKa₂ₓ and the write operation of the odd-numbered block BLKa₂ₓ₊₁ can be easily controlled.

The memory cell array 21 includes the first block group 211 and the second block group 212. The first block group 211 includes a plurality of blocks BLKa used as the cache area for temporarily storing data. The second block group 212 includes a plurality of blocks BLKb used as the storage area for storing data transmitted from the first block group 211. The even-numbered block BLKa₂ₓ and the odd-numbered block BLKa₂ₓ₊₁ are provided in the first block group 211.

According to this configuration, the write operation of the first block group 211 used as the cache area can be improved in terms of, for example a total operation time. The sequencer 24 may alternately execute the first program operation to one of the even-numbered blocks and the second program operation to one of the odd-numbered blocks. In this case, the write operation of the first block group 211 used as the cache area can be further improved.

### 1.11 Modification Example of Semiconductor Memory Device

Next, a modification example of the semiconductor memory device 2 according to the embodiment will be described.

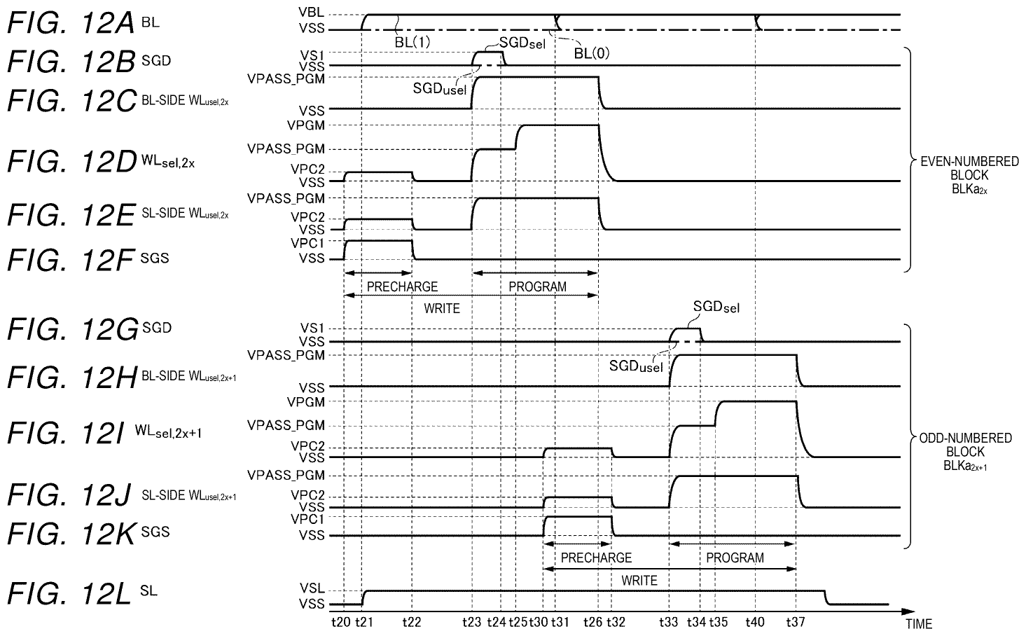

The semiconductor memory device 2 according to the present modification example performs the write operation of the memory cell array 21 using the ROP method illustrated in FIG. 5B. In this case, the voltage of each wire in the write operation of each of the even-numbered block BLKa₂ₓ and the odd-numbered block BLKa₂ₓ₊₁ of the first block group 211 changes as illustrated in FIGS. 12A to 12L.

As illustrated in FIGS. 12A to 12L, at time t20, the even-numbered row decoder 270 according to the present modification example applies the voltage VPC2 to the selected word line WL_{sel,2x} and the SL-side non-selected word line WL_{usel,2x} positioned closer to the source line SL than the selected word line WL_{sel,2x}. The even-numbered row decoder 270 applies the voltage VSS to the BL-side non-selected word line WL_{usel,2x} positioned closer to the bit line BL than the selected word line WL_{sel,2x}. The even-numbered row decoder 270 applies the voltage VPC1 to the select gate line SGS. Accordingly, the select transistor ST2 of each of the string units SU0 to SU3 of the even-numbered block BLKa₂ₓ enters the ON state. In the present modification example, the select transistor ST2 provided between the memory cell transistor MTa₂ₓ and the source line SL in the non-selected string unit SU₂ₓ is an example of a second select transistor.

Similarly, at time t30, the odd-numbered row decoder 271 applies the voltage VPC2 to the selected word line WL_{sel,2x+1} and the SL-side non-selected word line WL_{usel,2x+1} positioned closer to the source line SL than the selected word line WL_{sel,2x+1}. The odd-numbered row decoder 271 applies the voltage VSS to the BL-side non-selected word line WL_{usel,2x+1} positioned closer to the bit line BL than the selected word line WL_{sel,2x+1}. The odd-numbered row decoder 271 applies the voltage VPC1 to the select gate line SGS. Accordingly, the select transistor ST2 of each of the string units SU0 to SU3 of the odd-numbered block BLKa₂ₓ₊₁ enters the ON state. In the present modification example, the select transistor ST2 provided between the memory cell transistor MTₐ₂ₓ₊₁ and the source line SL in the non-selected string unit SU₂ₓ₊₁ is an example of a fourth select transistor.

According to this configuration, the same or similar action and effect as the embodiment can be obtained even in a case where the write operation of the memory cell array 21 is performed using the ROP method. In the present modification example, the precharge operation executed in the even-numbered block BLKa₂ₓ during the period from time t20 to time t22 is an example of a second precharge operation, and the precharge operation performed during the period from time t30 to time t32 is an example of a fourth precharge operation.

### 2 Other Embodiments

The present disclosure is not limited to the above specific examples.

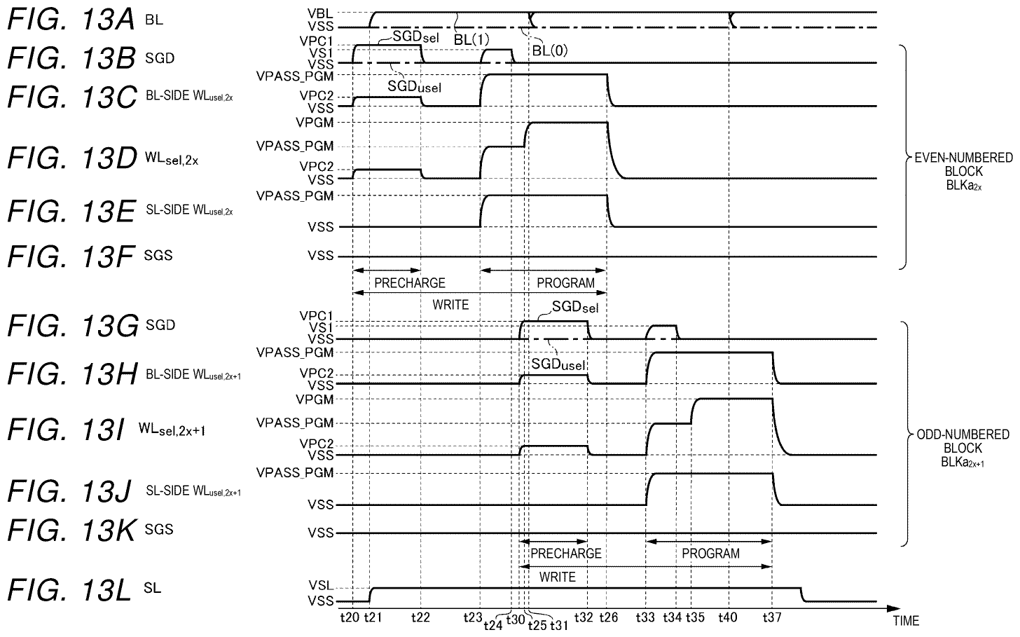

For example, the odd-numbered row decoder 271 may start the write operation of the odd-numbered block BLKa₂ₓ₊₁ at time t30 illustrated in FIGS. 13A to 13L. That is, the odd-numbered row decoder 271 may start the write operation of the odd-numbered block BLKa₂ₓ₊₁ during a period from time t24 to time t25, that is, a period before application of the voltage VPGM to the word line WL₂ₓ at time t25 after causing the memory cell transistor MTa₂ₓ to enter the floating state at time t24.

The configuration of the semiconductor memory device 2 according to the embodiment can be applied to not only a NAND flash memory but also any semiconductor memory device such as a solid state drive (SSD).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first block including a first memory cell transistor;
a first word line connected to a gate of the first memory cell transistor;
a second block including a second memory cell transistor;
a second word line connected to a gate of the second memory cell transistor;
a bit line connected to one end of the first memory cell transistor and one end of the second memory cell transistor; and
a control circuit configured to control the memory cell array, wherein
the control circuit is configured to:
execute a first write operation of writing first data into the first memory cell transistor by applying a first voltage to a first channel area of the first memory cell transistor through the bit line, then causing the first channel area of the first memory cell transistor to enter a floating state at a first timing, and while the first channel area of the first memory cell transistor is in the floating state, applying a program voltage to the first word line at a second timing, and
start a second write operation of writing second data into the second memory cell transistor that is connected to the bit line, at a third timing, which is during the first write operation and later than the first timing.

2. The semiconductor memory device according to claim 1, further comprising:
a plurality of other memory cell transistors in the first block and a first select transistor in the first block, wherein the first memory cell transistor and the plurality of other memory cell transistors are connected in series and share the first channel area, and the first select transistor is provided between the bit line and the first and other memory cell transistors that are connected in series; and
a plurality of other word lines respectively connected to the plurality of other memory cell transistors, wherein
the control circuit, in the first write operation,
executes a first program operation of applying the first voltage to the first channel area from the bit line by switching ON the first select transistor in a state where the first voltage is applied to the bit line, causing the first channel area to enter the floating state by switching OFF the first select transistor in a state where the first voltage is applied to the first channel area, and then applying the program voltage to the first word line and applying a write pass voltage lower than the program voltage to the other word lines.

3. The semiconductor memory device according to claim 2, wherein
the control circuit, in the first write operation,
executes a first precharge operation of applying the first voltage to the bit line and, in a state where the first select transistor is switched ON, applying a precharge voltage lower than the write pass voltage to the first word line and at least one of the other word lines that is between the bit line and the first word line, and
executes the first program operation following the first precharge operation.

4. The semiconductor memory device according to claim 2, further comprising:
a source line, wherein
the first block further includes a second select transistor provided between the source line and the first and other memory cell transistors that are connected in series, and
the control circuit, in the first write operation,
executes a second precharge operation of applying the first voltage to the bit line and, in a state where the second select transistor is switched ON, applying a precharge voltage lower than the write pass voltage to the first word line and at least one of the other word lines that is between the source line and the first word line, and
executes the first program operation following the second precharge operation.

5. The semiconductor memory device according to claim 2, wherein the third timing is prior to the second timing.

6. The semiconductor memory device according to claim 2, wherein the third timing is during a time period in which the program voltage is applied to the first word line.

7. The semiconductor memory device according to claim 1, further comprising:
a plurality of other memory cell transistors in the second block and a third select transistor in the second block, wherein the second memory cell transistor and the plurality of other memory cell transistors are connected in series and share a second channel area, and the third select transistor is provided between the bit line and the second and other memory cell transistors that are connected in series; and
a plurality of other word lines respectively connected to the plurality of other memory cell transistors, wherein the control circuit, in the second write operation,
executes a second program operation of applying a second voltage corresponding to the second data to the second channel area from the bit line by switching ON the third select transistor in a state where the second voltage is applied to the bit line, causing the second channel area of the second memory cell transistors to enter the floating state by switching OFF the third select transistor in a state where the second voltage is applied to the second channel area, and then applying the program voltage to the second word line and applying a write pass voltage lower than the program voltage to the other word lines.

8. The semiconductor memory device according to claim 7, wherein
the control circuit, in the second write operation,
executes a third precharge operation of applying the second voltage to the bit line and, in a state where the third select transistor is switched ON, applying a precharge voltage lower than the write pass voltage to the second word line and at least one of the other word lines that is between the bit line and the second word line, and
executes the second program operation following the third precharge operation.

9. The semiconductor memory device according to claim 7, further comprising:
a source line, wherein
the second block further includes a fourth select transistor provided between the source line and the second and other memory cell transistors that are connected in series, and
the control circuit, in the second write operation,
executes a fourth precharge operation of applying the second voltage to the bit line and, in a state where the fourth select transistor is switched ON, applying a precharge voltage lower than the write pass voltage to the second word line and at least one of the other word lines that is between the source line and the second word line, and
executes the second program operation following the fourth precharge operation.

10. The semiconductor memory device according to claim 1, further comprising:
a first row decoder connected to the first word line; and
a second row decoder that is different from the first row decoder and connected to the second word line,
wherein the control circuit is further configured to:
control a voltage of the first word line through the first row decoder, and
control a voltage of the second word line through the second row decoder.

11. The semiconductor memory device according to claim 1, further comprising:
a first block group including a plurality of cache blocks used as a cache area for temporarily storing data; and
a second block group including a plurality of storage blocks used as a storage area for storing data transmitted from the first block group, wherein
the first block and the second block are provided in the first block group.

12. The semiconductor memory device according to claim 1, wherein the control circuit alternately executes the first write operation and the second write operation.

13. A method of performing a write operation in a semiconductor memory device comprising a memory cell array including a first block and a second block, each of which includes a plurality of memory cell transistors, wherein the first block includes a first memory cell transistor of which a gate is connected to a first word line, and the second block includes a second memory cell transistor of which a gate is connected to a second word line, said method comprising:
executing a first write operation of writing first data into the first memory cell transistor by applying a first voltage to a channel area of the first memory cell transistor through a bit line, then causing the channel area of the first memory cell transistor to enter a floating state, and while the channel area of the first memory cell transistor is in the floating state, applying a program voltage to the first word line for a first time period; and
starting a second write operation of writing second data into the second memory cell transistor connected to the bit line during the first time period while the program voltage is applied to the first word line.

14. The method of claim 13, wherein
the first block further includes a first select transistor provided between the first memory cell transistor and the bit line, and
the first write operation includes the step of:
executing a first program operation of applying the first voltage to the channel area of the first memory cell transistor from the bit line by switching ON the first select transistor in a state where the first voltage is applied to the bit line, causing the channel area of the first memory cell transistor to enter the floating state by switching OFF the first select transistor in a state where the first voltage is applied to the channel area of the first memory cell transistor, and then applying the program voltage to the first word line and applying a write pass voltage lower than the program voltage to the second word line.

15. The method of claim 14, wherein the first write operation further includes the steps of:
executing a first precharge operation of applying the first voltage to the bit line and, in a state where the first select transistor is switched ON, applying a precharge voltage lower than the write pass voltage to the first word line and a non-selected word line that is between the first word line and the bit line, and
executing the first program operation following the first precharge operation.

16. The method of claim 14, wherein
the first block further includes a second select transistor provided between the first memory cell transistor and a source line, and
the first write operation further includes the steps of:
executing a second precharge operation of applying the first voltage to the bit line and, in a state where the second select transistor is switched ON, applying a precharge voltage lower than the write pass voltage to the first word line and the non-selected word line that is between the first word line and the bit line, and
executing the first program operation following the second precharge operation.

17. The method of claim 13, wherein
the second block further includes a third select transistor provided between the second memory cell transistor and the bit line, and
the second write operation includes the step of:
executing a second program operation of applying a second voltage corresponding to the second data to a channel area of the second memory cell transistor from the bit line by switching ON the third select transistor in a state where the second voltage is applied to the bit line, causing the channel area of the second memory cell transistor to enter the floating state by switching OFF the third select transistor in a state where the second voltage is applied to the channel area of the second memory cell transistor, and then applying the program voltage to the second word line and applying a write pass voltage lower than the program voltage to the first word line.

18. The method of claim 17, wherein the second write operation further includes the steps of:
executing a third precharge operation of applying the second voltage to the bit line and, in a state where the third select transistor is switched ON, applying a precharge voltage lower than the write pass voltage to the second word line and a non-selected word line that is between the first word line and the bit line, and
executing the second program operation following the third precharge operation.

19. The method of claim 17, wherein
the second block further includes a fourth select transistor provided between the second memory cell transistor and a source line, and
the second write operation further includes steps of:
executing a fourth precharge operation of applying the second voltage to the bit line and, in a state where the fourth select transistor is switched ON, applying a precharge voltage lower than the write pass voltage to the second word line and the non-selected word line that is between the first word line and the bit line, and
executing the second program operation following the fourth precharge operation.

20. The method of claim 13, wherein the semiconductor memory device further comprises:
a first row decoder connected to the first word line; and
a second row decoder that is different from the first row decoder and that is connected to the second word line,
wherein a voltage of the first word line is controlled through the first row decoder, and a voltage of the second word line is controlled through the second row decoder.

21. The method of claim 13, wherein
the memory cell array includes a first block group including a plurality of blocks used as a cache area for temporarily storing data, and a second block group including a plurality of blocks used as a storage area for storing data transmitted from the first block group, and
the first block and the second block are provided in the first block group.
